(19) United States
(12) Patent Application Publication
(10) Pub. No.: US 2025/0210329 A1
(43) Pub. Date: Jun. 26, 2025

(54) PLASMA PROCESSING APPARATUS, SUBSTRATE PROCESSING SYSTEM, AND FIXTURE

(71) Applicant: Tokyo Electron Limited, Tokyo (JP)

(72) Inventors: Koei ITO, Miyagi (JP); Norihiko AMIKURA, Miyagi (JP); Dai KITAGAWA, Miyagi (JP); Taisei SEGUCHI, Miyagi (JP)

(73) Assignee: Tokyo Electron Limited, Tokyo (JP)

(21) Appl. No.: 19/078,301

(22) Filed: Mar. 13, 2025

Related U.S. Application Data
(63) Continuation of application No. PCT/JP2025/021484, filed on Jun. 13, 2024.

(30) Foreign Application Priority Data
Jun. 28, 2023 (JP) 2023-105631
Apr. 9, 2024 (JP) 2024-062992

(51) Int. Cl. H01J 37/32

(52) U.S. Cl. CPC H01J 37/32733

(57) ABSTRACT

A plasma processing apparatus includes a chamber, a first member, a second member, and a fixture that detachably fixes the first member and the second member along an axial direction. The fixture includes a male member fixed to the first member, and a female member fixed to the second member and receiving the male member. The male member includes a shaft member extending in the axial direction and having an enlarged diameter at a tip thereof. The female member includes an accommodation member fixed to the second member, a holding member disposed within the accommodation member, and a spherical member held by the holding member. The spherical member moves inward in a radial direction by being guided by a tapered portion of an inner wall of the accommodation member when the holding member moves in a first direction, which is the axial direction toward an opening.

### CROSS-REFERENCE TO RELATED APPLICATIONS

This application is a continuation application of International Patent Application No. PCT/JP2024/021484, filed on Jun. 13, 2024, which claims priority from Japanese Patent Application Nos. 2023-105631 and 2024-062992, filed on Jun. 28, 2023 and Apr. 9, 2024, respectively, with the Japan Patent Office, the disclosure of each are incorporated herein in their entireties by reference.

### TECHNICAL FIELD

An embodiment of the present disclosure relates to a plasma processing apparatus, a substrate processing system, and a fixture.

### BACKGROUND

Japanese Patent Laid-Open Publication No. 2019-197830 discloses fastening an electrostatic chuck and an electrostatic chuck mounting plate by a plurality of first fasteners and fastening a stage, on which a substrate is placed, to a support member by a plurality of second fasteners.

### SUMMARY

In an embodiment of the present disclosure, a plasma processing apparatus including a chamber is provided. The plasma processing apparatus includes a first member, a second member, and a fixture that detachably fixes the first member and the second member along an axial direction. The fixture includes a male member fixed to the first member and a female member fixed to the second member and receiving the male member. The male member includes a shaft member extending in the axial direction and having an enlarged diameter at its tip. The female member includes an accommodation member fixed to the second member, a holding member disposed within the accommodation member, and a spherical member held by the holding member. The accommodation member includes an opening that receives the shaft member of the male member and an accommodation space that accommodates the holding member and the spherical member. The inner wall of the accommodation member, which defines the accommodation space, includes a tapered portion that decreases in diameter in the radial direction. The holding member is movable along the axial direction within the accommodation space while holding the spherical member. The spherical member moves inward in the radial direction by being guided by the tapered portion of the inner wall and when the holding member moves in a first direction, which is the axial direction toward the opening.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a plasma processing system.

FIG. 2 is a view illustrating a configuration example of a capacitively-coupled plasma processing apparatus.

FIG. 3 is a view schematically illustrating an example of a fixing structure FS.

FIGS. 4A and 4B are views illustrating an example of the movement position of spherical members.

FIGS. 5A to 5C are views illustrating an example of a method of using a fixture F.

FIGS. 6A and 6B are views illustrating another example of a driving mechanism of a holding member.

FIG. 7 is a view illustrating another example of the fixture F.

FIGS. 8A to 8C are views illustrating another example of the fixture F and its operation.

FIGS. 9A to 9C are views illustrating another example of the fixture F and its operation.

FIG. 10 is a view illustrating a configuration example of a substrate processing system PS.

FIG. 11 is a view illustrating an application example of the fixture F.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, each embodiment of the present disclosure will be described.

In an embodiment, a plasma processing apparatus including a chamber is provided. The plasma processing apparatus includes a first member, a second member, and a fixture detachably fixes the first member and the second member along an axial direction. The fixture includes a male member fixed to the first member and a female member fixed to the second member and receiving the male member. The male member includes a shaft member extending in the axial direction and having an enlarged diameter at its tip. The female member includes an accommodation member fixed to the second member, a holding member disposed within the accommodation member, and a spherical member held by the holding member. The accommodation member includes an opening that receives the shaft member of the male member and an accommodation space that accommodates the holding member and the spherical member. The inner wall of the accommodation member, which defines the accommodation space, includes a tapered portion that decreases in diameter in the radial direction. The holding member is movable along the axial direction within the accommodation space while holding the spherical member. The spherical member moves inward in the radial direction by being guided by the tapered portion of the inner wall and when the holding member moves in a first direction, which is the axial direction toward the opening.

In an embodiment, the holding member is moved in the first direction by an elastic member disposed within the accommodation space.

In an embodiment, the holding member is moved in the first direction by a first fluid flowing into the accommodation space.

In an embodiment, the holding member is moved in a second direction, which is opposite to the first direction, by a second fluid flowing into the accommodation space.

In an embodiment, the accommodation space includes a first space into which the first fluid flows and a second space into which the second fluid flows, and the first space and the second space are sealed from each other by a sealing member.

In an embodiment, the second space is provided closer to the opening than the first space, and the second space and the opening are sealed from each other by the sealing member.

In an embodiment, the holding member receives a force in the first direction or a force in the second direction, which is opposite to the first direction, via a cylinder or a motor.

In an embodiment, the holding member further includes a locking structure that restricts the movement of the spherical member inward in the radial direction.

In an embodiment, at least one of the first member and the second member is a member disposed within the chamber.

In an embodiment, at least one of the first member and the second member is a member constituting the chamber or a member disposed outside the chamber.

In an embodiment, in a state where the first member and the second member are fixed by the fixture, a sealing member is further provided to seal the gap between an external space of the chamber and the opening.

In an embodiment, at least one of the first member and the second member constitutes an electrode of the plasma processing apparatus, and the fixture provides a conductive path to the electrode by electrically connecting the male member and the female member to each other in a state where the first member and the second member are fixed by the fixture.

In an embodiment, a plasma processing apparatus including a chamber is provided. The plasma processing apparatus includes a first member, a second member, and a fixture configured to detachably fix the first member and the second member along an axial direction. The fixture includes a male member fixed to the first member and a female member fixed to the second member and configured to receive the male member. The female member includes a first moving body configured to be movable along the axial direction between a clamping position and an unclamping position, and a second moving body held by the first moving body. The second moving body is configured to move to a position where the second moving body restricts the axial movement of the male member in the clamping position and to a position where the second moving body does not hinder the axial movement of the male member in the unclamping position.

In an embodiment, at least one of the first member and the second member constitutes an electrode of the plasma processing apparatus, and the fixture is configured to provide a conductive path to the electrode by electrically connecting the male member and the female member to each other in the clamping position.

In an embodiment, a substrate processing system including one or more chambers is provided. The substrate processing system includes a first member, a second member, and a fixture that detachably fixes the first member and the second member along an axial direction. The fixture includes a male member fixed to the first member and a female member fixed to the second member and receiving the male member. The male member includes a shaft member extending in the axial direction and having an enlarged diameter at its tip. The female member includes an accommodation member fixed to the second member, a holding member disposed within the accommodation member, and a spherical member held by the holding member. The accommodation member includes an opening that receives the shaft member of the male member and an accommodation space that accommodates the holding member and the spherical member. The inner wall of the accommodation member, which defines the accommodation space, includes a tapered portion that decreases in diameter in the radial direction. The holding member is movable along the axial direction within the accommodation space while holding the spherical member. The spherical member moves inward in the radial direction by being guided by the tapered portion of the inner wall and when the holding member moves in a first direction, which is the axial direction toward the opening.

In an embodiment, the substrate processing system includes a transfer chamber including a wall surface provided with an opening communicating with the chamber, and an opening/closing device including a blocking portion that moves within the transfer chamber and to block the opening. The wall surface of the transfer chamber constitutes one of the first member and the second member, and the blocking portion of the opening/closing device constitutes the other of the first member and the second member.

In an embodiment, a fixture of a substrate processing system is provided. The fixture includes a male member including a shaft member and a female member that detachably fixes the shaft member of the male member. The female member includes a first moving body that is movable along an axial direction between a clamping position and an unclamping position, a second moving body that is held by the first moving body and moves to a position where the second moving body restricts the axial movement of the shaft member of the male member in the clamping position and to a position where the second moving body does not hinder the axial movement of the shaft member of the male member in the unclamping position, and a third moving body that presses the shaft member of the male member and moves the shaft member along the axial direction in the unclamping position.

In an embodiment, a fixture of a substrate processing system is provided. The fixture includes a female member including an inner wall defining an accommodation space and an engagement portion provided on a portion of the inner wall, and a male member including a shaft member that is movable along the axial direction within the accommodation space and a moving body moves between a clamping position, where the moving body engages with the engagement portion of the female member in accordance with the axial movement of the shaft member, and an unclamping position, where the moving body does not engage with the engagement portion of the female member. The shaft member presses the inner wall of the female member while moving in the axial direction when the engagement portion is in the unclamping position.

In an embodiment, a substrate processing system is provided. The substrate processing system includes the fixture, a transfer chamber including a wall surface provided with an opening communicating with the chamber, and an opening/closing device including a blocking portion that moves within the transfer chamber and to block the opening. One of the male member and the female member is provided on the wall surface of the transfer chamber, and the other of the male member and the female member is directed toward the blocking portion of the opening/closing device.

Hereinafter, each embodiment of the present disclosure will be described in detail with reference to the drawings. In the drawings, identical or similar elements are denoted by the same reference numerals, and redundant descriptions are omitted. Unless otherwise specified, positional relationships, such as upper, lower, left, and right, will be described based on the positional relationships illustrated in the drawings. The dimensional ratios in the drawings do not represent actual ratios, and actual ratios are not limited to the illustrated ratios.

### <Configuration Example of Plasma Processing System>

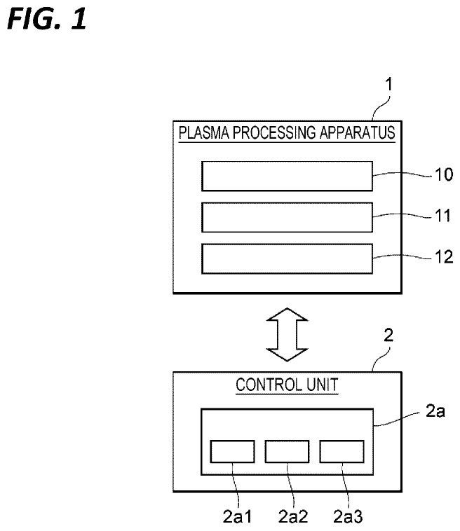

FIG. 1 is a view illustrating a configuration example of a plasma processing system. In an embodiment, the plasma processing system includes a plasma processing apparatus 1 and a control unit 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. In addition, the plasma processing chamber 10 has at least one gas supply port that supplies at least one processing gas to the plasma processing space, and at least one gas discharge port that discharges gas from the plasma processing space. The gas supply port is connected to a gas supply unit 20 to be described later, and the gas discharge port is connected to an exhaust system 40 to be described later. The substrate support unit 11 is arranged in the plasma processing space and has a substrate support surface supports a substrate.

The plasma generation unit 12 generates plasma from at least one processing gas supplied into the plasma processing space. The plasma formed in the plasma processing space may be, for example, capacitively-coupled plasma (CCP), inductively-coupled plasma (ICP), electron-cyclotron-resonance (ECR) plasma, helicon wave plasma (HWP), or surface wave plasma (SWP). In addition, various types of plasma generation units including an alternating current (AC) plasma generation unit and a direct current (DC) plasma generation unit may be used. In an embodiment, an AC signal (AC power) used in the AC plasma generation unit has a frequency in the range of 100 kHz to 10 GHz. Therefore, the AC signal includes a radio frequency (RF) signal and a microwave signal. In an embodiment, the RF signal has a frequency within the range of 100 kHz to 150 MHz.

The control unit 2 processes computer-executable commands that cause the plasma processing apparatus 1 to execute various processes described in the present disclosure. The control unit 2 may control each element of the plasma processing apparatus 1 to perform various steps described herein. In an embodiment, a part or all of the control unit 2 may be included in the plasma processing apparatus 1. The control unit 2 may include a processor 2a1, a storage 2a2, and a communication interface 2a3. The control unit 2 is implemented by, for example, a computer 2a. The processor 2al may perform various control operations by reading a program from the storage 2a2 and executing the read program. This program may be stored in the storage 2a2 in advance, or may be acquired via a medium when necessary. The acquired program is stored in the storage 2a2 to be read from the storage 2a2 and executed by the processor 2a1. The medium may be various storage media readable by the computer 2a, or may be a communication line connected to the communication interface 2a3. The processor 2a1 may be a central processing unit (CPU). The storage 2a2 may include random access memory (RAM), read-only memory (ROM), hard disk drive (HDD), solid state drive (SSD), or a combination thereof. The communication interface 2a3 may communicate with the plasma processing apparatus 1 via a communication line such as a local area network (LAN).

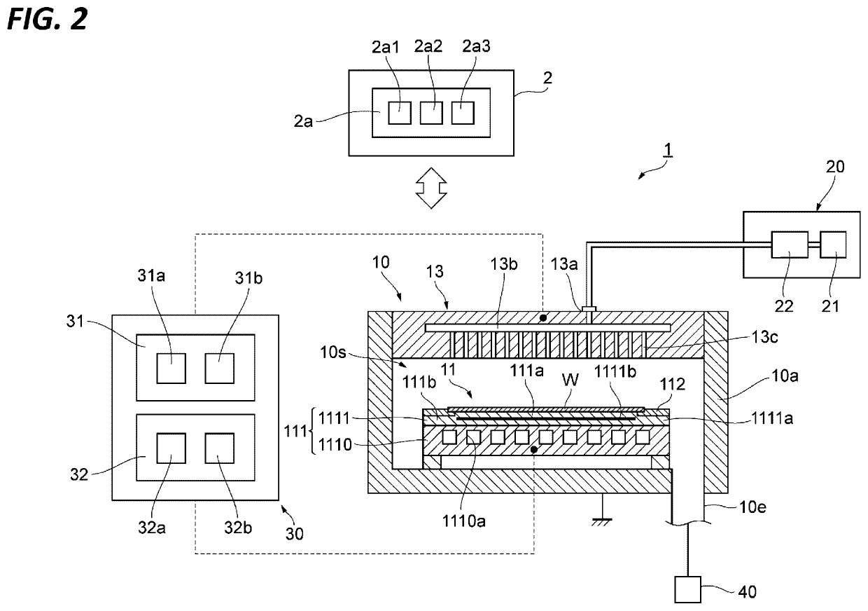

A configuration example of a capacitively-coupled plasma processing apparatus as an example of the plasma processing apparatus 1 will be described below. FIG. 2 is a view illustrating a configuration example of a capacitively-coupled plasma processing apparatus.

The capacitively-coupled plasma processing apparatus 1 includes a plasma processing chamber 10, a gas supply unit 20, a power supply 30, and an exhaust system 40. In addition, the plasma processing apparatus 1 includes a substrate support unit 11 and a gas injector. The gas injector is configured to inject at least one processing gas into the plasma processing chamber 10. The gas injector includes a showerhead 13. The substrate support unit 11 is disposed in the plasma processing chamber 10. The showerhead 13 is disposed above the substrate support unit 11. In an embodiment, the showerhead 13 constitutes at least a portion of the ceiling of the plasma processing chamber 10. The plasma processing chamber 10 has a plasma processing space 10s defined by the showerhead 13, the side wall 10a of the plasma processing chamber 10, and the substrate support unit 11. The plasma processing chamber 10 is grounded. The showerhead 13 and the substrate support unit 11 are electrically insulated from the housing of the plasma processing chamber 10.

The substrate support unit 11 includes a main body 111 and a ring assembly 112. The main body 111 includes a central region 111a that supports a substrate W and an annular region 111b supports the ring assembly 112. A wafer is an example of substrate W. The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W on the central region 111a of the main body 111. Accordingly, the central region 111a is also referred to as a “substrate support surface” that supports a substrate W, and the annular region 111b is also referred to as a “ring support surface” that supports the ring assembly 112.

In an embodiment, the main body 111 includes a base 1110 and an electrostatic chuck 1111. The base 1110 includes a conductive member. The conductive member of the base 1110 may serve as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has an annular region 111b. In addition, another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 to be described below may be disposed within the ceramic member 1111a. In this case, the at least one RF/DC electrode serves as a lower electrode. When a bias RF signal and/or a DC signal, which will be described below, is supplied to the at least one RF/DC electrode, the RF/DC electrode is also referred to as a “bias electrode.” In addition, the conductive member of the base 1110 and the at least one RF/DC electrode may function as a plurality of lower electrodes. Furthermore, the electrostatic electrode 1111b may function as a lower electrode. Accordingly, the substrate support unit 11 includes at least one lower electrode.

The ring assembly 112 includes one or more annular members. In an embodiment, the one or more annular members include one or more edge rings and at least one cover ring. The edge rings are made of a conductive material or an insulating material, and the cover ring is made of an insulating material.

In addition, the substrate support unit 11 may include a temperature regulating module that regulates at least one of the electrostatic chuck 1111, the ring assembly 112, and the substrate to a target temperature. The temperature regulating module may include a heater, a heat transfer medium, a flow path 1110a, or a combination thereof. A heat transfer fluid, such as brine or gas, flows through the flow path 1110a. In an embodiment, the flow path 1110a is formed inside the base 1110, and one or more heaters are disposed inside the ceramic member 1111a of electrostatic chuck 1111. In addition, the substrate support unit 11 may include a heat transfer gas supply unit that supplies a heat transfer gas to the gap between the rear surface of the substrate W and the central region 111a.

The showerhead 13 is configured to inject at least one processing gas from the gas supply unit 20 into the plasma processing space 10s. The showerhead 13 includes at least one gas supply port 13a, at least one gas diffusion chamber 13b, and a plurality of gas injection ports 13c. The processing gas supplied to the gas supply port 13a passes through the gas diffusion chamber 13b and is introduced into the plasma processing space 10s from the plurality of gas introduction ports 13c. In addition, the showerhead 13 includes at least one upper electrode. In addition to the showerhead 13, the gas injector may include one or more side gas injectors (SGIs) installed in one or more openings formed in the side wall 10a.

The gas supply unit 20 may include one or more gas sources 21 and one or more flow rate controllers 22. In an embodiment, the gas supply unit 20 is configured to supply at least one processing gas from a corresponding one of the gas sources 21 to the showerhead 13 via a corresponding one of the flow rate controllers 22. Each flow rate controller 22 may include, for example, a mass flow controller or a pressure-controlled flow rate controller. The gas supply unit 20 may include at least one flow rate modulation device that modulates or pulses the flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is generated from the at least one processing gas supplied into the plasma processing space 10s. Therefore, the RF power supply 31 may function as at least a part of the plasma generation unit 12. In addition, by supplying a bias RF signal to the at least one lower electrode, a bias potential may be generated in the substrate W, and an ionic component in the formed plasma may be drawn into the substrate W.

In an embodiment, the RF power supply 31 includes a first RF generation unit 31a and a second RF generation unit 31b. The first RF generation unit 31a is coupled to the at least one lower electrode and/or the at least one upper electrode via at least one impedance matching circuit to generate a source RF signal (source RF power) for plasma generation. In an embodiment, the RF signal has a frequency within the range of 10 MHz to 150 MHz. In an embodiment, the first RF generation unit 31a may be configured to generate a plurality of source RF signals having different frequencies. One or more generated source RF signals are provided to the at least one lower electrode and/or the at least one upper electrode.

The second RF generation unit 31b is coupled to the at least one lower electrode via the at least one impedance matching circuit and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency within the range of 100 kHz to 60 MHz. In an embodiment, the second RF generation unit 31a may be configured to generate a plurality of bias RF signals having different frequencies. One or more generated bias RF signals are provided to the at least one lower electrode. In addition, in various embodiments, at least one of the source RF signal and the bias RF signal may be pulsed.

The power supply 30 may include a DC power supply 32 coupled to the plasma processing chamber 10. The DC power supply 32 includes a first DC generation unit 32a and a second DC generation unit 32b. In an embodiment, the first DC generation unit 32a is connected to the at least one lower electrode and configured to generate a first DC signal. The generated first DC signal is applied to the at least one lower electrode. In an embodiment, the second DC generation unit 32b is connected to the at least one upper electrode and configured to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or a combination thereof. In an embodiment, a waveform generation unit that generates a sequence of voltage pulses from a DC signal is connected across the first DC generation unit 32a and the at least one lower electrode. Therefore, the first DC generation unit 32a and the waveform generation unit constitute a voltage pulse generation unit. When the second DC generation unit 32b and the waveform generation unit constitute a voltage pulse generation unit, the voltage pulse generation unit is connected to at least one upper electrode. The voltage pulses may have a positive polarity or a negative polarity. The sequence of voltage pulses may include one or more positive polarity voltage pulses and one or more negative polarity voltage pulses within one cycle. The first DC generation unit 32a and the second DC generation unit 32b may be provided in addition to the RF power supply 31, and the first DC generation unit 32a may be provided in place of the second RF generation unit 31b.

The exhaust system 40 may be connected to a gas exhaust port 10e provided, for example, at the bottom of the plasma processing chamber 10. The exhaust system 40 may include a pressure regulating valve and a vacuum pump. By the pressure regulating valve, the pressure in the plasma processing space 10s is regulated. The vacuum pump may include a turbo molecular pump, a dry pump, or a combination thereof.

### <Example of Fixture F>

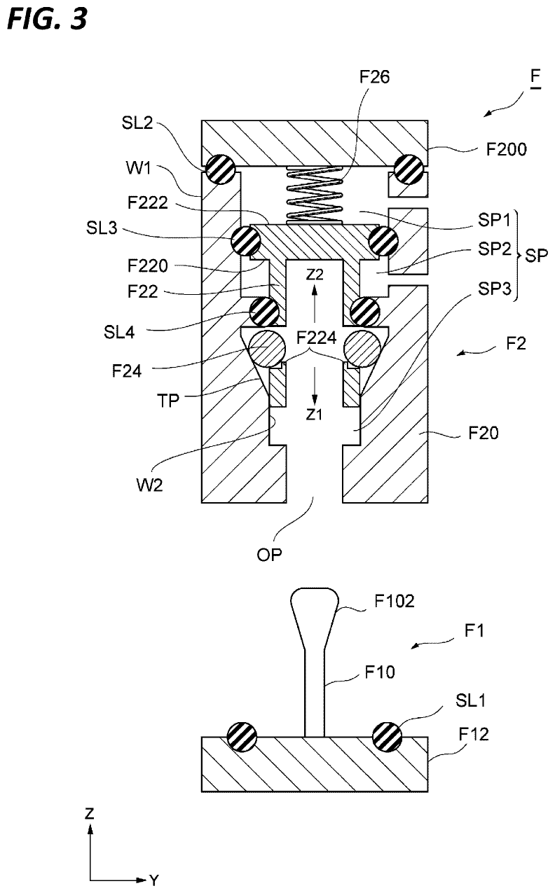

FIG. 3 is a schematic view illustrating an example of a fixture F according to an embodiment. In an embodiment, the fixture F may be used to fix structural members of the plasma processing apparatus 1 illustrated in FIGS. 1 and 2. The fixture F is configured to detachably fix two members of the plasma processing apparatus 1 along an axial direction (the Z-axis direction in FIG. 3). The axial direction may vary depending on the arrangement of the structural members fixed by the fixture F. The axial direction may be a direction perpendicular to the horizontal plane of the plasma processing apparatus 1 (the vertical direction in FIG. 2), a direction parallel thereto (the horizontal direction in FIG. 2), or an oblique direction.

As illustrated in FIG. 3, the fixture F includes a male member F1 and a female member F2. The male member F1 is fixed to a first member CP1 (not illustrated), which is a structural member of the plasma processing apparatus 1. The female member F2 is fixed to a second member CP2 (not illustrated), which is also a structural member of the plasma processing apparatus 1.

In an embodiment, at least one of the first member CP1 and the second member CP2 may be a member disposed inside the plasma processing chamber 10 (hereinafter also referred to as “chamber 10”), such as an electrostatic chuck 1111 or a base 1110. For example, the first member CP1 may be the electrostatic chuck 1111, and the second member CP2 may be the base 1110. Alternatively, for example, the first member CP1 may be the base 1110, and the second member CP2 may be the electrostatic chuck 1111. In an embodiment, the first member CP1 and/or the second member CP2 may constitute a lower electrode of the plasma processing apparatus 1. In an embodiment, at least one of the first member CP1 and the second member CP2 may be a member constituting the chamber 10, such as a showerhead 13 or a side wall 10a. For example, the first member CP1 may be the showerhead 13, and the second member CP2 may be the side wall 10a. Alternatively, for example, the first member CP1 may be the side wall 10a, and the second member CP2 may be the showerhead 13. In addition, when the showerhead 13 is constituted by a plurality of members, the first member CP1 may be one of the members of the showerhead 13 (e.g., a ceiling plate facing the plasma processing space 10s), and the second member CP2 may be another member of the showerhead 13 (e.g., a support supporting the ceiling plate). In an embodiment, the first member CP1 and/or the second member CP2 may constitute an upper electrode of the plasma processing apparatus 1. In an embodiment, at least one of the first member CP1 and the second member CP2 may be a member located outside the chamber 10 (e.g., the gas supply unit 20 or the exhaust system 40).

In an embodiment, the first member CP1 and the second member CP2 may be constituted by one or more components. In an embodiment, at least one of the first member CP1 and the second member CP2 may be a replaceable component due to, for example, wear or modification.

As illustrated in FIG. 3, the male member F1 includes a shaft member F10 extending along the axial direction (the Z direction). The shaft member F10 includes a head portion F102 having an enlarged diameter at one axial end. The male member F1 may further include a support member F12 that supports the other end of the shaft member F10. In an embodiment, the male member F1 may be fixed to the first member CP1 (not illustrated) by fixing the support member F12 to the first member CP1. In an embodiment, a first sealing member SL1 may be provided on the surface of the support member F12.

In an embodiment, the male member F1 may not include the support member F12. In this case, the male member F1 may be fixed to the first member CP1 by fixing the other end of the shaft member F10 to the first member CP1.

As illustrated in FIG. 3, the female member F2 includes an accommodation member F20, a holding member F22 disposed within the accommodation member F20, and spherical members F24 held by the holding member F22.

The accommodation member F20 includes an outer wall W1 and an inner wall W2. In an embodiment, the outer wall W1 of the accommodation member F20 is at least partially fixed to the second member CP2 (not illustrated).

In an embodiment, a portion of the second member CP2 may form a portion of the outer wall W1 and the inner wall W2 of the accommodation member F20. For example, the upper end F200 of the accommodation member F20 in FIG. 3 may be a portion of the second member CP2 or may be integrated with the second member CP2. In this case, a second sealing member SL2 may be provided to seal the gap between the upper end F200 of the accommodation member F20 and the remaining portion thereof.

The inner wall W2 of the accommodation member F20 defines an accommodation space SP and an opening OP. The accommodation space SP accommodates, for example, the holding member F22, and the spherical members F24. In an embodiment, the accommodation space SP may be divided into a plurality of sealed spaces. For example, in the example illustrated in FIG. 3, the accommodation space SP is divided into a first space SP1, a second space SP2, and a third space SP3 in order from the distal side to the proximal side of the opening OP. The first space SP1 and the second space SP2 may be configured to receive a first fluid FL1 and a second fluid FL2, respectively. In this case, the first space SP1 communicates with an opening through which the first fluid FL1 flows in and/or out. The second space SP2 communicates with an opening through which the second fluid FL2 flows in and/or out. The third space SP3 is a space where the spherical members F24 are disposed. In an embodiment, a third sealing member SL3 may be provided between the first space SP1 and the second space SP2. In an embodiment, a fourth sealing member SL4 may be provided between the second space SP2 and the third space SP3.

The opening OP communicates with the third space SP3. The opening OP has a diameter larger than that of the head portion F102 of the shaft member F10. Accordingly, the shaft member F10 may be inserted into or withdrawn from the accommodation space SP through the opening OP. The inner wall W2 defining the third space SP3 includes a tapered portion TP. As illustrated in FIG. 3, the tapered portion TP decreases in diameter along a first direction (the Z1 direction in FIG. 3), which is the axial direction toward the opening OP. The tapered portion TP functions as a guide member that guides the spherical members F24 in the radial direction (the Y-axis direction in FIG. 3).

The holding member F22 is configured to be movable along the axial direction within the accommodation space SP while holding the spherical members F24. Specifically, the holding member F22 is movable in both the first direction toward the opening OP and the second direction (the Z2 direction in FIG. 3), which is opposite to the first direction. That is, the holding member F22 is capable of reciprocating along the axial direction within the accommodation space SP. The holding member F22 is an example of a first moving body.

In an embodiment, the second fluid FL2 may flow into the second space SP2. The movement of the holding member F22 in the second direction may be caused by the first surface F220 (the surface oriented in the first direction) of the holding member F22, which is pressed by the second fluid FL2 flowing into the second space SP2.

In an embodiment, an elastic member F26 (e.g., a compression spring) may be disposed in the first space SP1. The movement of the holding member F22 in the first direction may be caused by the second surface F222 (the surface oriented in the second direction) of the holding member F22, which is pressed by the elastic member F26. In an embodiment, the first fluid FL1 may flow into the first space SP1. The movement of the holding member F22 in the first direction may be caused by the second surface F222 of the holding member F22, which is pressed by the first fluid FL1 flowing into the first space SP1. In an embodiment, the movement of the holding member F22 in the first direction may be caused by the second surface F222 of the holding member F22, which is pressed by both the elastic member F26 and the second fluid FL2.

In an embodiment, the holding member F22 may include a locking structure that restricts the movement of the spherical members F24 inward in the radial direction (Y-axis direction in FIG. 3). The locking structure may be, for example, a projection F224 as illustrated in FIG. 3.

The spherical members F24 are held by the holding member F22. When the spherical members F24 moves in the axial direction (the Z-axis direction in FIG. 3) due to the movement of the holding member F22, the spherical members F24 are simultaneously guided by the tapered portion TP of the inner wall W2 and move along the radial direction (the Y-axis direction in FIG. 3). The spherical members F24 is an example of a second moving body. In an embodiment, two or more spherical members F24 may be provided.

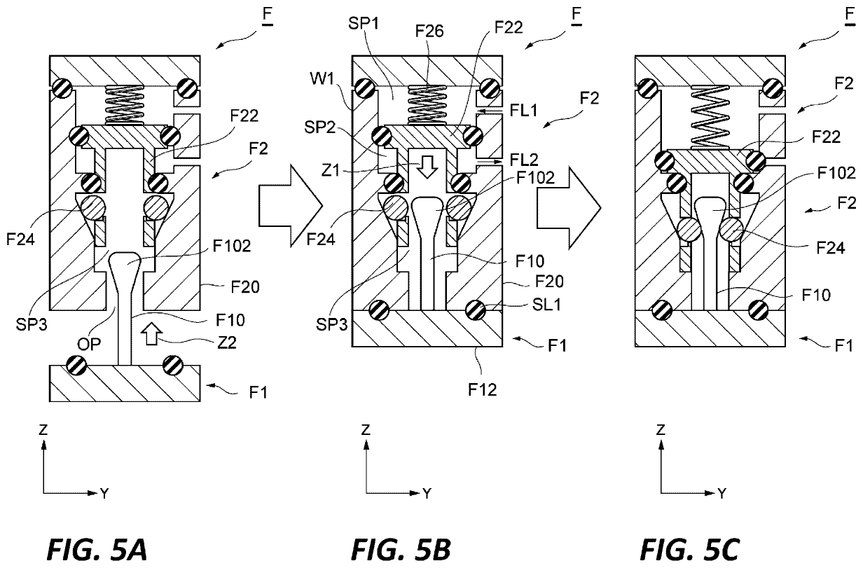

As described above, the first member CP1 and the second member CP2 may constitute a part of an electrode (the upper electrode or the lower electrode) of the plasma processing apparatus 1. In such a case, in an embodiment, the male member F1 and the female member F2 of the fixture F may be configured to be electrically connectable to each other. For example, the support member F12 of the male member F1, the shaft member F10, the spherical members F24 of the female member F2, the holding member F22, the elastic member F26, and the upper end F200 of the accommodation member F20 may be made of conductive materials. As illustrated in FIG. 5C, when the male member F1 is fixed to the female member F2 in a state where movement in the axial direction is restricted, the shaft member F10 comes into contact with the spherical members F24. As a result, a conductive path for current is formed through the support member F12 of the male member F1, the shaft member F10, the spherical members F24 of the female member F2, the holding member F22, the elastic member F26, and the upper end F200 of the accommodation member F20. Accordingly, the male member F1 and the female member F2 are electrically connected. That is, the fixture F may function as a conductive path between the first member CP1 and the second member CP2 in the state where the first member CP1 and the second member CP2 are fixed. For example, when the first member CP1 and the second member CP2 are fixed, a current supplied to the first member CP1 may be supplied to the second member CP2 via the fixture F. For example, in the state where the first member CP1 and the second member CP2 are fixed, a current supplied to the second member CP2 may be supplied to the first member CP1 via the fixture F.

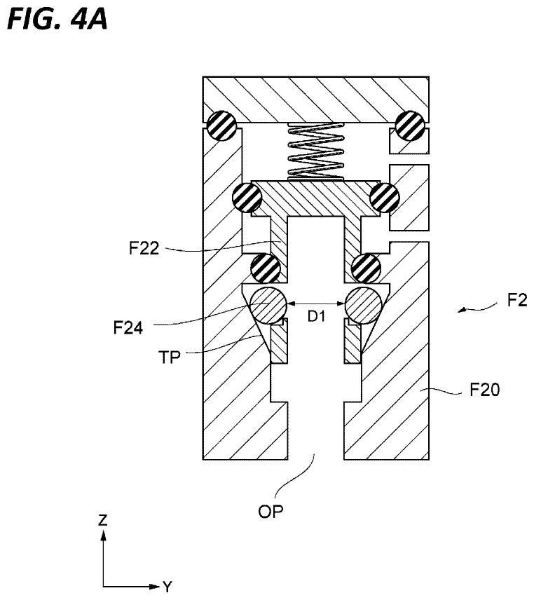

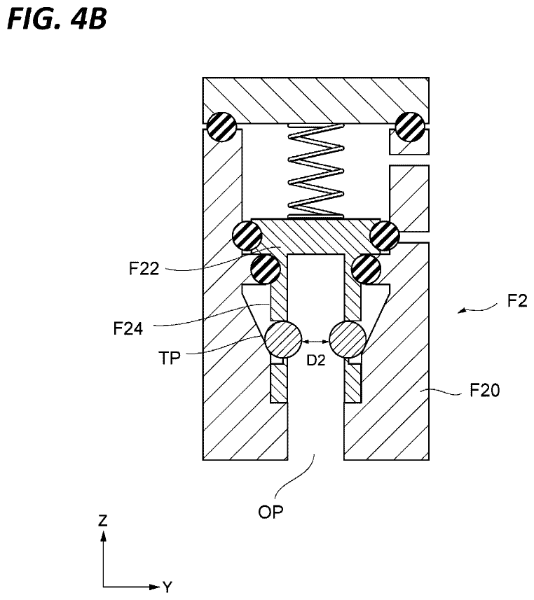

FIGS. 4A and 4B are views illustrating examples of the movement positions of the spherical members. FIG. 4A illustrates an example of a state where the holding member F22 is maximally moved in the second direction (the direction away from the opening OP) (hereinafter referred to as an “unclamping position”). FIG. 4B illustrates an example of a state where the holding member F22 is maximally moved in the first direction (the direction toward the opening OP) (hereinafter referred to as a “clamping position”).

As illustrated in FIG. 4A, in the unclamping position, the spherical members F24 are in contact with the upper portion (the distal side with respect to the opening OP) of the tapered portion TP. At this time, the radial distance between the spherical members F24 is D1. The distance D1 is greater than the maximum width of the head portion F102 of the shaft member F10. As illustrated in FIG. 4B, in the clamping position, the spherical members F24 are in contact with the lower portion (the proximal side with respect to the opening OP) of the tapered portion TP. At this time, the radial distance between the spherical members F24 is D2. The distance D2 is smaller than the maximum width of the head portion F102 of the shaft member F10.

### <Example of Use of Fixture F>

FIGS. 5A to 5C are views illustrating an example of a method of using the fixture F. FIGS. 5A to 5C illustrate an example of a method for fixing the male member F1 (and the first member CP1 fixed to the male member F1) of the fixture F to the female member F2 (and the second member CP2 fixed to the female member F2).

First, the male member F1 of the fixture F is moved toward the female member F2 in the second direction (the Z2 direction in FIGS. 5A to 5C). Alternatively, the female member F2 may be moved toward the male member F1 in the first direction. Then, the shaft member F10 of the male member F1 is inserted toward the third space SP3 through the opening OP of the accommodation member F20 (see, e.g., FIG. 5A). At this time, the holding member F22 of the female member F2 is in the unclamping position.

When the support member F12 of the male member F1 comes into contact with the outer wall W1 of the accommodation member F20 of the female member F2, the shaft member F10 of the male member F1 is positioned inside the third space SP3 of the accommodation member F20 (see, e.g., FIG. 5B). Next, the second fluid FL2 is discharged from the second space SP2. Then, the holding member F22 of the female member F2 is moved in the first direction (the Z1 direction in FIGS. 5A to 5C) by the elastic member F26. At this time, to facilitate movement in the first direction, the first fluid FL1 may be introduced into the first space SP1.

When the holding member F22 of the female member moves to the clamping position, the radial distance between the spherical members F24 decreases, and the head portion F102 of the shaft member F10 is clamped between the spherical members F24 (see, e.g., FIG. 5C). The movement of the spherical members F24 outward in the radial direction is restricted by the tapered portion TP of the inner wall W2. Therefore, the movement of the shaft member F10 in the axial direction is restricted. As a result, the male member F1 is fixed to the female member F2 so as to be immovable in the axial direction. Consequently, the first member CP1 is fixed to the second member CP2. When removing the male member F1 of the fixture F from the female member F2 (removing the first member CP1 from the second member CP2), the above procedure may be reversed.

By using the fixture F, attachment and detachment between members of the plasma processing apparatus 1 may be performed by mechanically operating the fixture F without using fasteners (e.g., screws). Accordingly, attachment and detachment of structural members in the plasma processing apparatus 1 may be easily performed. By using the fixture F, compared to using fasteners, the number of work steps and the work time required for assembly of the plasma processing apparatus and for maintenance, such as replacement of consumables and modifications, may be reduced.

### <Other Examples of Drive Mechanism of Holding Member>

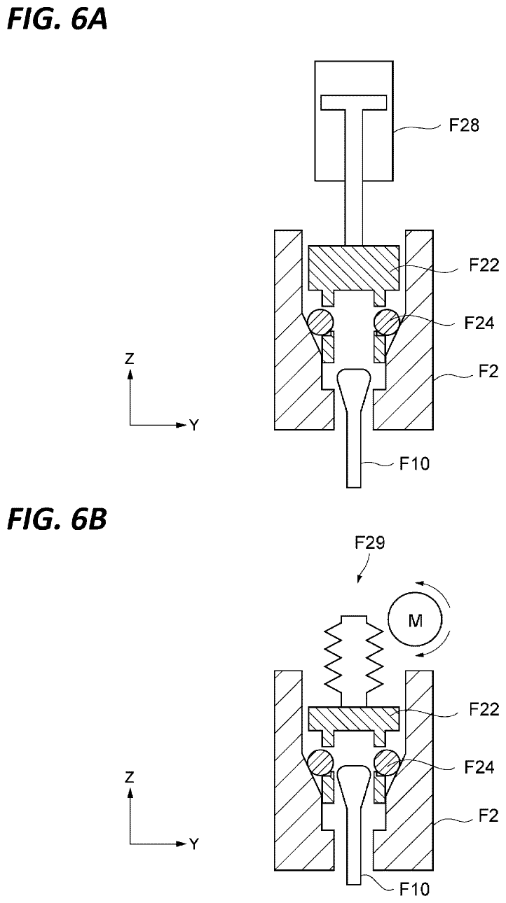

FIGS. 6A and 6B are views illustrating other examples of the drive mechanism of the holding member. In an embodiment, as illustrated in FIG. 6A, the upper end of the holding member F22 of the female member F2 may be connected to a cylinder member F28. The cylinder member F28 may be configured to reciprocate along the axial direction and thereby apply a force to the holding member F22 in the first direction and the second direction. In an embodiment, as illustrated in FIG. 6B, the upper end of the holding member F22 of the female member F2 may be connected to a rack of a rack-and-pinion system F29. The rack-and-pinion system F29 transmits the rotational motion of a motor to the rack via a pinion gear. The rack may be configured to reciprocate along the axial direction according to the rotational direction of the motor, and thereby to apply a force to the holding member F22 in the first direction and the second direction.

### <Other Examples of Fixture F>

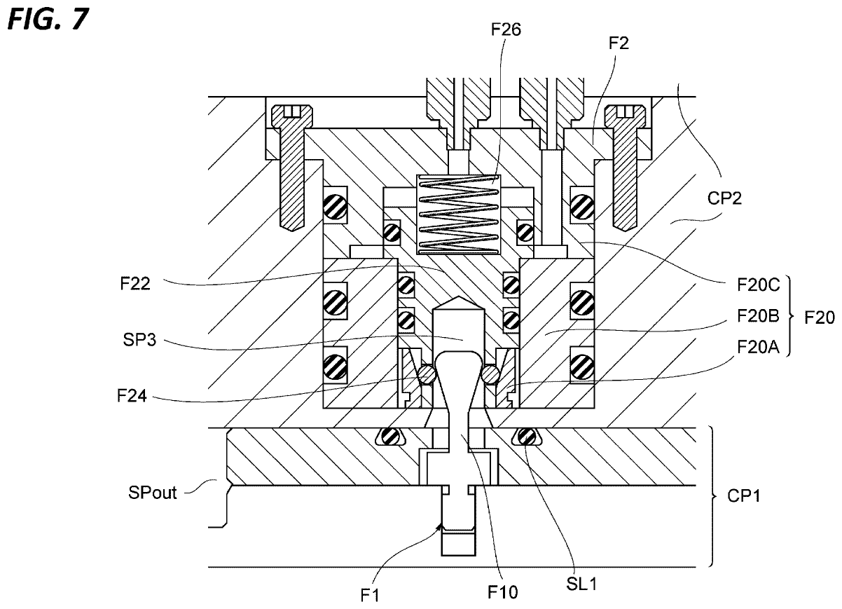

FIG. 7 is a view illustrating another example of the fixture F. In the example illustrated in FIG. 7, the shaft member F10 of the male member F1 is fixed with its other end embedded in the first member CP1. In addition, the female member F2 is fixed with its entirety embedded in the second member CP2. In an embodiment, a first sealing member SL1 may be disposed on the opposing surfaces of the first member CP1 and the second member CP2. The first sealing member SL1 seals the gap between an external space SPout (e.g., a space outside the chamber 10) and the opening OP of the accommodation member F20.

In an embodiment, each component of the fixture F may be constituted by a plurality of parts. For example, as illustrated in FIG. 7, the accommodation member F20 of the female member F2 may be constituted by a plurality of parts F20A to F20C.

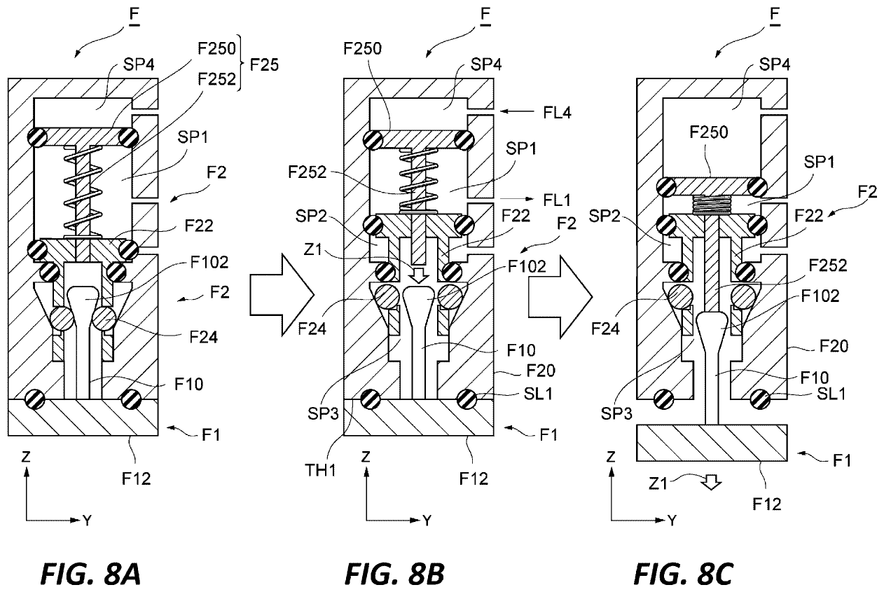

FIGS. 8A to 8C are views illustrating another example of the fixture F and its operation. In the example illustrated in FIGS. 8A to 8C, the female member F2 includes a pressing member F25 that presses the shaft member F10 of the male member F1. The pressing member F25 is disposed within the accommodation space SP of the accommodation member F20 and is configured to be movable in the axial direction. The pressing member F25 includes a head portion F250 and a shaft portion F252 extending axially from the center of the head portion F250. The accommodation space SP includes a fourth space SP4 and a first space SP1, which are separated by the head portion F250. The tip of the shaft portion F252 extends through the central portion of the holding member F22. The pressing member F25 is an example of a third moving body.

When the holding member F22 moves from the clamping position (see, e.g., FIG. 8A) to the unclamping position (see, e.g., FIG. 8B), the engagement between the spherical members F24 and the head portion F102 of the shaft member F10 is released. In this state, the fourth fluid FL4 flows into the fourth space SP4. Then, the pressing member F25 is moved in the first direction (the Z1 direction in FIG. 8B). At this time, the first fluid FL1 may flow out from the first space SP1, or the first space SP1 may be sealed to prevent the first fluid FL1 from flowing out.

As the pressing member F25 moves in the first direction, the shaft portion F252 comes into contact with the head portion F102 of the shaft member F10 and pushes the shaft member F10 along the first direction (see, e.g., FIG. 8C). As a result, the female member F2 (and the second member CP2) and the male member F1 (and the first member CP1) are separated from each other (hereinafter referred to as an “ejection position”).

Meanwhile, even when the holding member F22 is in the unclamping position (see, e.g., FIG. 8B), the male member F1 and the female member F2 may sometimes adhere to each other, for example, at their boundary surface TH1. In such a case, unless the adhesion is released, the two members may not be separated. In addition, it is difficult to detect whether adhesion has actually occurred in a non-contact manner.

In this regard, in the configuration illustrated in FIGS. 8A to 8C, the pressing member F25, which presses the shaft member F10 of the male member F1, is provided at the unclamping position (see, e.g., FIG. 8B). Accordingly, even if adhesion occurs, the male member F1 and the female member F2 may be separated (see, e.g., FIG. 8C).

In an embodiment, during the transition from the unclamping position (see, e.g., FIG. 8B) to the ejection position (see, e.g., FIG. 8C), the first space SP1 may be sealed, and the pressure within the first space SP1 may be detected. This allows the detection of whether the pressing member F25 has actually reached the ejection position. For example, when the pressure in the first space SP1 rises to a predetermined level after a certain period of time, it is determined that the pressing member F25 has moved to the ejection position. Conversely, when the pressure in the first space SP1 does not reach the predetermined level after a given period of time, it is determined that the pressing member F25 has not moved to the ejection position (indicating that the male member F1 and the female member F2 strongly adhere to each other). This allows detecting whether the male member F1 and the female member F2 have actually been separated.

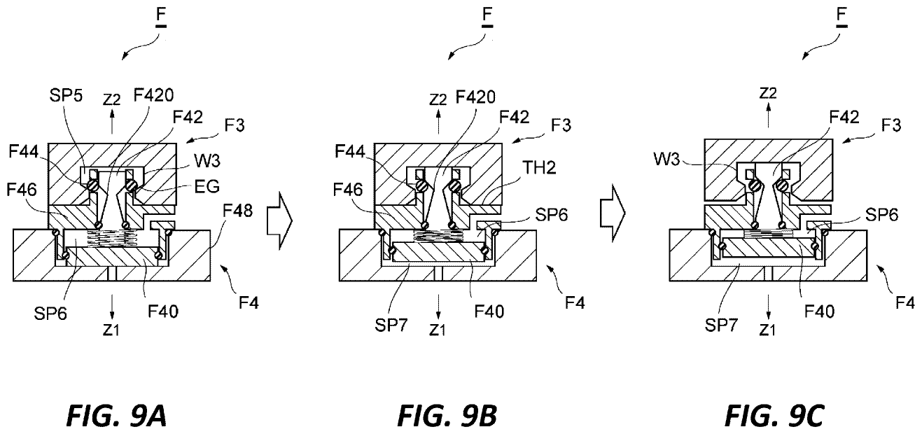

FIGS. 9A to 9C are views illustrating another example of the fixture F and its operation. In the example illustrated in FIGS. 9A to 9C, the fixture F includes a female member F3 and a male member F4. The female member F3 includes an inner wall W3 defining an accommodation space SP5. A portion of the inner wall W3 includes a tapered engagement portion EG that increases in diameter in the radial direction.

The male member F4 includes a support base F40, a shaft member F42, spherical members F44, a holding member F46, and an accommodation member F48.

The support base F40 is disposed within the accommodation space of the accommodation member F48 and defines a sixth space SP6 and a seventh space SP7. The support base F40 moves in the first direction (the Z1 direction) along the axial direction or in the second direction (the Z2 direction), opposite to the first direction, in response to the inflow or outflow of fluid into or from the sixth space SP6 and the seventh space SP7. The shaft member F42 is fixed on the support base F40 and moves in the first and second directions within the accommodation space SP5 as the support base F40 moves. The shaft member F42 includes a head portion F420 that decreases in diameter along the axial direction.

The spherical members F44 moves between the clamping position and the unclamping position when the female member F3 and the male member F4 are in contact with each other.

Specifically, when fluid flows into the sixth space SP6, the support base F40 and the shaft member F42 move in the first direction (the Z1 direction), causing the spherical members F44 to move outward in the radial direction (here, the axial movement of the spherical members F44 is restricted by the holding member F46). As a result, the spherical members F44 engage with the engagement portion EG of the female member F3 (see, e.g., FIG. 9A). This position is the clamping position, where the female member F3 and the male member F4 are fixed so as to be immovable in the axial direction.

When fluid flows into the seventh space SP7 and the support base F40 and the shaft member F42 move in the second direction (the Z2 direction), the spherical members F44 moves inward in the radial direction along the head portion F420 of the shaft member F42 (here, the axial movement of the spherical members F44 is restricted by the holding member F46). As a result, the engagement between the spherical members F44 and the engagement portion EG of the female member F3 is released (see, e.g., FIG. 9B). This position is the unclamping position, where the female member F3 and the male member F4 become movable in the axial direction.

In this state, fluid may further flow into the seventh space SP7. Then, the support base F40 and the shaft member F42 move further in the second direction. At this time, the fluid may be discharged from the sixth space SP6, or the sixth space SP6 may be sealed to prevent the fluid from flowing out. As the support base F40 and the shaft member F42 move in the second direction, the shaft member F42 pushes the inner wall W3 of the female member F3 along the second direction (see, e.g., FIG. 9C). As a result, the female member F3 and the male member F4 are separated from each other (hereinafter referred to as a “separation position”).

Meanwhile, even when the spherical members F44 are in the unclamping position (see, e.g., FIG. 9B), the female member F3 and the male member F4 may adhere to each other, for example, at the boundary surface TH2 thereof. In such a case, unless the adhesion is released, the two members may not be separated. In addition, it is difficult to detect whether adhesion has actually occurred in a non-contact manner.

In this regard, in the configuration illustrated in FIGS. 9A to 9C, the support base F40 and the shaft member F42 are moved in the second direction from the unclamping position (see, e.g., FIG. 9B), thereby pressing the inner wall W3 of the female member F3 in the second direction (see, e.g., FIG. 9C). Accordingly, the female member F3 and the male member F4 may be separated even if adhesion occurs therebetween. During the transition from the unclamping position (see, e.g., FIG. 9B) to the separation position (see, e.g., FIG. 9C), the sixth space SP6 may be sealed, and the pressure within the sixth space SP6 may be detected. When the pressure in the sixth space SP6 rises to a predetermined level after a certain period of time, it is determined that the support base F40 and the shaft member F42 have moved to the separation position. Conversely, when the pressure in the sixth space SP6 does not reach the predetermined level after the certain period of time, it is determined that the support base F40 and the shaft member F42 have not moved to the separation position (indicating that the female member F3 and the male member F4 strongly adhere to each other). This allows detecting whether the female member F3 and the male member F4 have actually been separated.

### <Application Example to Substrate Processing System>

In an embodiment, the above-described fixture F may be used to fix structural members of a substrate processing system (hereinafter referred to as a “substrate processing system PS”) including one or more chambers.

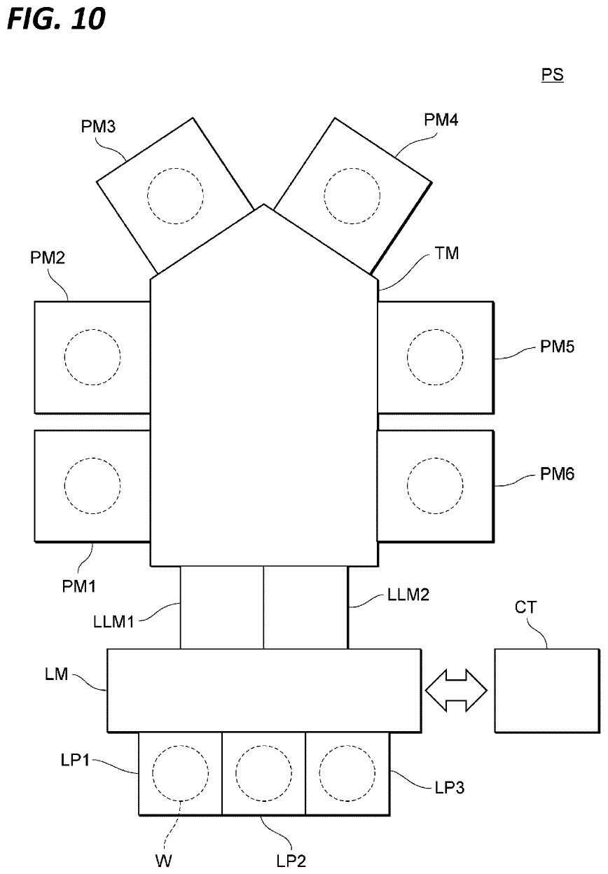

FIG. 10 is a view illustrating a configuration example of the substrate processing system PS. The substrate processing system PS includes substrate processing chambers PM1 to PM6 (hereinafter collectively referred to as “substrate processing modules PM”), a transfer module TM, load lock modules LLM1 and LLM2 (hereinafter collectively referred to as “load lock modules LLM”), a loader module LM, and load ports LP1 to LP3 (hereinafter collectively referred to as “load ports LP”). A control unit CT controls each component of the substrate processing system PS to execute predetermined processing on a substrate W.

The substrate processing modules PM perform processing, such as etching, trimming, film formation, annealing, doping, lithography, cleaning, and ashing on a substrate W. At least one of the substrate processing chambers PM1 to PM6 may be the chamber 10 of the plasma processing apparatus 1 illustrated in FIG. 1 or FIG. 2. In addition, at least one of the substrate processing chambers PM1 to PM6 may be a plasma processing apparatus that uses any plasma source, such as an inductively-coupled plasma or microwave plasma. At least one of the substrate processing chambers PM1 to PM6 may be a measurement module and may measure, for example, the thickness of a film formed on a substrate W or the dimensions of a pattern formed on a substrate W using, for example, an optical method.

The transfer module TM has a transfer apparatus that transfers substrates W, and transfers a substrate W between the substrate processing modules PM or between the substrate processing modules PM and the load lock modules LLM. The substrate processing modules PM and the load lock modules LLM are arranged adjacent to the transfer module TM. The transfer module TM and the substrate processing modules PM and load lock modules LLM are spatially isolated or connected by gate valves capable of being opened and closed.

In an embodiment, the transfer apparatus included in the transfer module TM transfers a substrate W from the transfer module TM to the plasma processing space 10s of a plasma processing apparatus 1, which is an example of the substrate processing modules PM. The transfer device places a substrate W on the central region 111a of a substrate support unit 11. The plasma processing apparatus 1 may include a lifter, and the transfer device may place a substrate W on the lifter. The lifter is configured to move up and down within a plurality of through-holes provided in the substrate support unit 11. When the lifter moves up, its tip protrudes from the central region 111a of the substrate support unit 11, and the substrate W is held at this position. When the lifter moves down, the tip of the lifter is accommodated within the substrate support unit 11, and the substrate W is placed on the central region 111a of the substrate support unit 11. As an example, the transfer device may be a handler that transfers a substrate such as a silicon wafer.

The load lock modules LLM1 and LLM2 are provided between the transfer module TM and the loader module LM. The load lock module LLM may switch its internal pressure between atmospheric pressure and vacuum. The “atmospheric pressure” may be the pressure external to each module included in the substrate processing system PS. The “vacuum” is a pressure lower than the atmospheric pressure and may be, for example, a medium vacuum in a range of 0.1 Pa to 100 Pa. The load lock modules LLM transfer a substrate W from the loader module LM under atmospheric pressure to the transfer module TM under vacuum, and also transfer a substrate W from the transfer module TM under vacuum to the loader module LM under atmospheric pressure.

The loader module LM includes a transfer apparatus that transfers a substrate W between the load-lock modules LLM and the load ports LP. The interiors of the load ports LP may each accommodate, for example, a front opening unified pod (FOUP) capable of storing 25 substrates W or an empty FOUP. The loader module LM takes out a substrate W from the FOUPs in the load ports LP and transfers the substrate to the load lock modules LLM. In addition, the loader module LM takes out a substrate W from the load lock modules LLM and transfers the substrate to the FOUPs in the load ports LP.

The control unit CT controls each component of the substrate processing system PS to perform given processing on a substrate W. The control unit CT stores a recipe in which, for example, process procedures, process conditions, and transfer conditions are set, and controls each component of the substrate processing system PS to perform given processing on a substrate W according to the recipe. The control unit CT may perform part or all of the functions of the control unit 2 illustrated in FIG. 1.

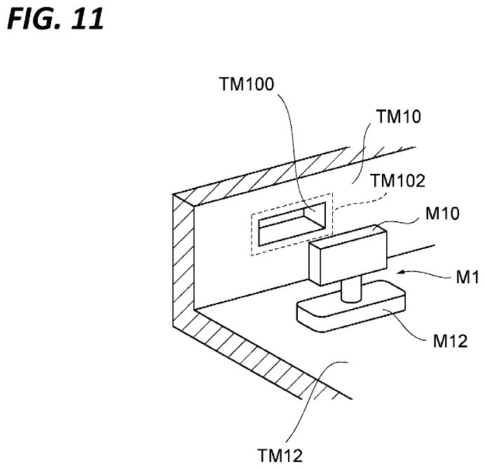

FIG. 11 is a view illustrating an application example of the fixture F in the above-described substrate processing system PS. As illustrated in FIG. 11, a transfer module TM includes an opening TM100 provided in a portion of a wall surface TM10 constituting a vacuum chamber. In an example, the opening TM100 communicates with the substrate processing module PM. In another example, the opening TM100 communicates with a load lock module LLM.

Inside the transfer module TM, an opening/closing device M1 that opens and closes the opening TM100 is provided. The opening/closing device M1 includes a blocking portion M10 and a base M12. The opening/closing device M1 moves along a floor surface TM12 of the transfer module TM. When the opening/closing device M1 moves to a position facing the opening TM100 and presses the blocking portion M10 against the opening TM100, the opening TM100 is sealed. When the opening/closing device M1 moves to another position, the sealing of the opening TM100 by the blocking portion M10 is released.

In an embodiment, a plurality of coils may be arranged on the floor surface TM12 of the transfer module TM, and permanent magnets may be provided on the base M12 of the opening/closing device M1. In this case, when current is supplied to each coil on the floor surface TM12, a magnetic field is generated on the floor surface TM12, causing the opening/closing device M1 to levitate magnetically and move along the floor surface TM12. By controlling the current value of each coil, the position, orientation, and levitation height of the opening/closing device M1 may be controlled.

In an embodiment, the fixture F may be used to fix the wall surface TM10 of the transfer module TM and the opening/closing device M1. For example, the female member F2 or F3 of the fixture F may be provided in a region TM102 surrounding the opening TM100 on the wall surface TM10, and the male member F1 or F4 may be provided at a corresponding position on the blocking portion M10. Alternatively, for example, the male member F1 or F4 of the fixture F may be provided in the region TM102, and the female member F2 or F3 may be provided at a corresponding position on the blocking portion M10. One or more fixtures F may be provided.

By using the fixture F, the blocking portion M10 of the opening/closing device M1 and the wall surface TM10 may be more firmly fixed. This suppresses fluid leakage through the opening TM100 even when there is a large pressure difference between the communication destination of the opening TM100 and the transfer module TM. In addition, by using the fixture F, the blocking portion M10 and the wall surface TM10 are mechanically fixed to each other. This allows a reduction in the power required to fix the position of the opening/closing device M1, for example, when the opening/closing device M1 is driven magnetically.

Embodiments of the present disclosure further includes the following aspects.

### APPENDIX 1

A plasma processing apparatus including a chamber, the plasma processing apparatus including:
a first member;
a second member; and
a fixture configured to detachably fix the first member and the second member along an axial direction, the fixture including a male member fixed to the first member, and a female member fixed to the second member and configured to receive the male member,
in which the male member includes a shaft member extending in the axial direction and having an enlarged diameter at a tip thereof,
in which the female member includes an accommodation member fixed to the second member, a holding member disposed within the accommodation member, and a spherical member held by the holding member,
in which the accommodation member includes an opening configured to receive the shaft member of the male member, and an accommodation space configured to accommodate the holding member and the spherical member, in which an inner wall of the accommodation member defining the accommodation space includes a tapered portion decreasing in diameter in a radial direction,
in which the holding member is configured to be movable along the axial direction within the accommodation space while holding the spherical member, and
in which the spherical member is guided by the tapered portion of the inner wall and moves inward in the radial direction when the holding member moves in a first direction, which is the axial direction toward the opening.

### APPENDIX 2

The plasma processing apparatus of Appendix 1, in which the holding member is moved in the first direction by an elastic member disposed within the accommodation space.

### APPENDIX 3

The plasma processing apparatus of Appendix 1 or 2, in which the holding member is moved in the first direction by a first fluid flowing into the accommodation space.

### APPENDIX 4

The plasma processing apparatus of any one of Appendices 1 to 3, in which the holding member is moved in a second direction opposite to the first direction by a second fluid flowing into the accommodation space.

### APPENDIX 5

The plasma processing apparatus of any one of Appendices 1 to 4, in which the accommodation space includes a first space into which the first fluid flows, and a second space into which the second fluid flows, and the first space and the second space are sealed from each other by a sealing member.

### APPENDIX 6

The plasma processing apparatus of Appendix 5, in which the second space is provided on an opening side relative to the first space, and the second space and the opening are sealed from each other by a sealing member.

### APPENDIX 7

The plasma processing apparatus of any one of Appendices 1 to 6, in which the holding member is configured to receive a force in the first direction or the second direction via a cylinder or a motor.

### APPENDIX 8

The plasma processing apparatus of any one of Appendices 1 to 7, in which the holding member further includes a locking structure configured to restrict movement of the spherical member inward in the radial direction.

### APPENDIX 9

The plasma processing apparatus of any one of Appendices 1 to 8, in which at least one of the first member and the second member is a member disposed within the chamber.

### APPENDIX 10

The plasma processing apparatus of any one of Appendices 1 to 9, in which at least one of the first member and the second member is a member constituting the chamber or a member disposed outside the chamber.

### APPENDIX 11

The plasma processing apparatus of any one of Appendices 1 to 10, further including a sealing member configured to seal a gap between an external space of the chamber and the opening in a state where the first member and the second member are fixed by the fixture.

### APPENDIX 12

The plasma processing apparatus of any one of Appendices 1 to 11, in which at least one of the first member and the second member constitutes an electrode of the plasma processing apparatus, and the fixture is configured to provide a conductive path to the electrode by electrically connecting the male member and the female member in a state where the first member and the second member are fixed by the fixture.

### APPENDIX 13

A plasma processing apparatus including a chamber, the plasma processing apparatus including:
a first member; a second member; and a fixture configured to detachably fix the first member and the second member along an axial direction, the fixture including a male member fixed to the first member, and a female member fixed to the second member and configured to receive the male member,
in which the female member includes: a first moving body configured to be movable along the axial direction between a clamping position and an unclamping position; and a second moving body held by the first moving body and configured to move to a position where the second moving body restricts the axial movement of the male member in the clamping position and to a position where the second moving body does not hinder the axial movement of the male member in the unclamping position.

### APPENDIX 14

The plasma processing apparatus of Appendix 13, in which at least one of the first member and the second member constitutes an electrode of the plasma processing apparatus, and the fixture is configured to provide a conductive path to the electrode by electrically connecting the male member and the female member in the clamping position.

### APPENDIX 15

A substrate processing system including one or more chambers, the substrate processing system including:
a first member;
a second member; and
a fixture configured to detachably fix the first member and the second member along an axial direction, the fixture including a male member fixed to the first member, and a female member fixed to the second member and configured to receive the male member,
in which the male member includes a shaft member extending in the axial direction and having an enlarged diameter at a tip thereof,
in which the female member includes an accommodation member fixed to the second member, a holding member disposed within the accommodation member, and a spherical member held by the holding member,
in which the accommodation member includes an opening configured to receive the shaft member of the male member, and an accommodation space configured to accommodate the holding member and the spherical member, in which an inner wall of the accommodation member defining the accommodation space includes a tapered portion decreasing in diameter in a radial direction,
in which the holding member is configured to be movable along the axial direction within the accommodation space while holding the spherical member, and
in which the spherical member is guided by the tapered portion of the inner wall and moves inward in the radial direction when the holding member moves in a first direction, which is the axial direction toward the opening.

### APPENDIX 16

The substrate processing system of Appendix 15, further including:
a transfer chamber including a wall surface provided with an opening communicating with the chamber; and
an opening/closing device including a blocking portion configured to move within the transfer chamber and to close the opening,
in which the wall surface of the transfer chamber constitutes one of the first member and the second member, and the blocking portion of the opening/closing device constitutes the other of the first member and the second member.

### APPENDIX 17

A fixture of a substrate processing system, the fixture including:
a male member including a shaft member; and
a female member configured to detachably fix the shaft member of the male member,
in which the female member includes:
a first moving body configured to be movable along an axial direction between a clamping position and an unclamping position;
a second moving body held by the first moving body and configured to move to a position where the second moving body restricts the axial movement of the shaft member of the male member in the clamping position and to a position where the second moving body does not hinder the axial movement of the shaft member of the male member in the unclamping position; and
a third moving body configured to press the shaft member of the male member and to move the shaft member along the axial direction in the unclamping position.

### APPENDIX 18

A fixture of a substrate processing system, the fixture including:
a female member including an inner wall defining an accommodation space, and an engagement portion provided on a portion of the inner wall;
a male member including a shaft member configured to be movable along the axial direction within the accommodation space; and
a moving body configured to move between a clamping position where the moving body engages with the engagement portion of the female member in accordance with the axial movement of the shaft member, and an unclamping position where the moving body does not engage with the engagement portion of the female member,
in which the shaft member is configured to move in the axial direction and to press the inner wall of the female member in a state where the engagement portion is in the unclamping position.

### APPENDIX 19

A substrate processing system including:
a fixture of Appendix 17 or Appendix 18;
a transfer chamber including a wall surface provided with an opening communicating with the chamber; and
an opening/closing device including a blocking portion configured to move within the transfer chamber and to close the opening,
in which one of the male member and the female member is provided on the wall surface of the transfer chamber, and the other of the male member and the female member faces the blocking portion of the opening/closing device.

An embodiment of the present disclosure may provide a technology that facilitates attachment and detachment between structural members of a plasma processing apparatus or a substrate processing system.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus including a chamber, the plasma processing apparatus comprising:
a first member;
a second member; and
a fixture configured to detachably fix the first member and the second member along an axial direction, the fixture including a male member fixed to the first member, and a female member fixed to the second member and configured to receive the male member,
wherein the male member includes a shaft extending in the axial direction and having an enlarged diameter at a tip thereof,
the female member includes a housing fixed to the second member, a holder disposed within the housing, and a spherical portion held by the holder,
the housing includes an opening configured to receive the shaft of the male member, and an accommodation space configured to accommodate the holder and the spherical portion, in which an inner wall of the housing defining the accommodation space includes a tapered portion decreasing in diameter in a radial direction,
the holder is configured to be movable along the axial direction within the accommodation space while holding the spherical portion, and
the spherical portion is guided by the tapered portion of the inner wall and moves inward in the radial direction when the holder moves in a first direction, which is the axial direction toward the opening.

2. The plasma processing apparatus according to claim 1, wherein the holder is moved in the first direction by a spring disposed within the accommodation space.

3. The plasma processing apparatus according to claim 2, wherein the holder is moved in the first direction by a first fluid flowing into the accommodation space.

4. The plasma processing apparatus according to claim 3, wherein the holder is moved in a second direction opposite to the first direction by a second fluid flowing into the accommodation space.

5. The plasma processing apparatus according to claim 4, wherein the accommodation space includes a first space into which the first fluid flows, and a second space into which the second fluid flows, and the first space and the second space are sealed from each other by a seal.

6. The plasma processing apparatus according to claim 5, wherein the second space is provided on an opening side relative to the first space, and the second space and the opening are sealed from each other by a seal.

7. The plasma processing apparatus according to claim 1, wherein the holder is configured to receive a force in the first direction or the second direction via a cylinder or a motor.

8. The plasma processing apparatus according to claim 1, wherein the holder further includes a locking structure configured to restrict movement of the spherical portion inward in the radial direction.

9. The plasma processing apparatus according to claim 1, wherein at least one of the first member and the second member is disposed within the chamber.

10. The plasma processing apparatus according to claim 1, wherein at least one of the first member and the second member constitutes the chamber or is disposed outside the chamber.

11. The plasma processing apparatus according to claim 10, further comprising:
a seal configured to seal a gap between an external space of the chamber and the opening in a state where the first member and the second member are fixed by the fixture.

12. The plasma processing apparatus according to claim 1, wherein at least one of the first member and the second member constitutes an electrode of the plasma processing apparatus, and the fixture is configured to provide a conductive path to the electrode by electrically connecting the male member and the female member in a state where the first member and the second member are fixed by the fixture.

13. A plasma processing apparatus including a chamber, the plasma processing apparatus comprising:
a first member;
a second member; and
a fixture configured to detachably fix the first member and the second member along an axial direction, the fixture including a male member fixed to the first member, and a female member fixed to the second member and configured to receive the male member,
wherein the female member includes: a first moving body configured to be movable along the axial direction between a clamping position and an unclamping position; and a second moving body held by the first moving body and configured to move to a position where the second moving body restricts the axial movement of the male member in the clamping position and to a position where the second moving body does not hinder the axial movement of the male member in the unclamping position.

14. The plasma processing apparatus according to claim 13, wherein at least one of the first member and the second member constitutes an electrode of the plasma processing apparatus, and the fixture is configured to provide a conductive path to the electrode by electrically connecting the male member and the female member in the clamping position.

15. A substrate processing system including one or more chambers, the substrate processing system comprising:
a first member;
a second member; and
a fixture configured to detachably fix the first member and the second member along an axial direction, the fixture including a male member fixed to the first member, and a female member fixed to the second member and configured to receive the male member,
wherein the male member includes a shaft extending in the axial direction and having an enlarged diameter at a tip thereof,
the female member includes a housing fixed to the second member, a holder disposed within the housing, and a spherical portion held by the holder,
the housing includes an opening configured to receive the shaft of the male member, and an accommodation space configured to accommodate the holder and the spherical portion, in which an inner wall of the housing defining the accommodation space includes a tapered portion decreasing in diameter in a radial direction,
the holder is configured to be movable along the axial direction within the accommodation space while holding the spherical portion, and
the spherical portion is guided by the tapered portion of the inner wall and moves inward in the radial direction when the holder moves in a first direction, which is the axial direction toward the opening.

16. The substrate processing system of according to claim 15, further comprising:
a transfer chamber including a wall surface provided with an opening communicating with the chamber; and
an opening/closing device including a blocking portion configured to move within the transfer chamber and to close the opening,
wherein the wall surface of the transfer chamber constitutes one of the first member and the second member, and the blocking portion of the opening/closing device constitutes the other of the first member and the second member.

17. A fixture of a substrate processing system, the fixture comprising:
a male member including a shaft; and
a female member configured to detachably fix the shaft of the male member,
wherein the female member includes:
a first moving body configured to be movable along an axial direction between a clamping position and an unclamping position;
a second moving body held by the first moving body and configured to move to a position where the second moving body restricts the axial movement of the shaft of the male member in the clamping position and to a position where the second moving body does not hinder the axial movement of the shaft of the male member in the unclamping position; and
a third moving body configured to press the shaft of the male member and to move the shaft along the axial direction in the unclamping position.

18. A fixture of a substrate processing system, the fixture comprising:
a female member including an inner wall defining an accommodation space, and an engagement portion provided on a portion of the inner wall;
a male member including a shaft configured to be movable along the axial direction within the accommodation space; and
a moving body configured to move between a clamping position where the moving body engages with the engagement portion of the female member in accordance with the axial movement of the shaft, and an unclamping position where the moving body does not engage with the engagement portion of the female member,
wherein the shaft is configured to move in the axial direction and to press the inner wall of the female member in a state where the engagement portion is in the unclamping position.

19. A substrate processing system comprising:
the fixture of claim 17;
a transfer chamber including a wall surface provided with an opening communicating with the chamber; and
an opening/closing device including a blocking portion configured to move within the transfer chamber and to close the opening,
wherein one of the male member and the female member is provided on the wall surface of the transfer chamber, and the other of the male member and the female member faces the blocking portion of the opening/closing device.
